(19) United States
(12) Patent Application Publication
(10) Pub. No.: US 2019/0020178 A1
(43) Pub. Date: Jan. 17, 2019

(54) LASER APPARATUS

(71) Applicant: FURUKAWA ELECTRIC CO., LTD., Tokyo (JP)

(72) Inventors: Atsushi OGURI, Tokyo (JP); Etsuji KATAYAMA, Tokyo (JP); Yuta ISHIGE, Tokyo (JP); Toshio KIMURA, Tokyo (JP); Yutaka OHKI, Tokyo (JP); Hajime MORI, Tokyo (JP)

(73) Assignee: FURUKAWA ELECTRIC CO., LTD., Tokyo (JP)

(21) Appl. No.: 16/054,462

(22) Filed: Aug. 3, 2018

Related U.S. Application Data
(63) Continuation of application No. PCT/JP2016/085521, filed on Nov. 30, 2016.
(60) Provisional application No. 62/290,671, filed on Feb. 3, 2016.

(51) Int. Cl. H01S 5/40; H01S 5/14; H01S 5/06; H01S 5/065; H01S 5/022

(52) U.S. Cl. CPC H01S 5/4012; H01S 5/142; H01S 5/0607; H01S 5/02288; H01S 5/02284; H01S 5/4087; H01S 5/0653

(57) ABSTRACT

A laser apparatus includes light source elements outputting laser beams; a wavelength-selecting element disposed in an optical path of each of the laser beams and configured to cause light in a predetermined wavelength band to selectively transmit therethrough; and a partially transmissive-reflector that receives the light transmitted through the wavelength-selecting element, reflects a part of the input light toward the wavelength-selecting element, and causes its remainder to transmit therethrough. The wavelength-selecting element causes a part of the respective laser beams output from the respective light source elements to selectively transmit therethrough, the partially transmissive-reflector reflects a part of the respective transmitted laser beams, and the wavelength-selecting element causes a part of the respective reflected laser beams to transmit to return to the light source elements, and each of the light source elements preferentially oscillates at a wavelength of the laser beam that transmits through the wavelength-selecting element.

### CROSS-REFERENCE TO RELATED APPLICATION(S)

This application is a continuation of International Application No. PCT/JP2016/085521, filed on Nov. 30, 2016 which claims the benefit of priority of U.S. Provisional Application No. 62/290,671, filed on Feb. 3, 2016, the entire contents of which are incorporated herein by reference.

### BACKGROUND OF THE INVENTION

### 1. Field of the Invention

The present disclosure relates to a laser apparatus.

### 2. Description of the Related Art

For example, as a laser apparatus as a processing tool, a laser apparatus has been developed that has a configuration in which laser beams output from semiconductor laser elements are condensed and applied onto an object has been developed. The laser apparatus having such a configuration is also called a direct diode laser (DDL).

It is difficult to precisely control a laser emission wavelength of light source elements such as semiconductor laser elements to a desired wavelength at the time of element manufacture. However, in such a laser apparatus, it may be required to control the laser emission wavelength of the light source element to a desired wavelength. For example, depending on the application of the laser apparatus, there is a case where a wavelength range permitted for a laser beam is narrow or an optimum wavelength range is different for use. In addition, in a case where laser beams having different wavelengths output from the plurality of light source elements are multiplexed and output from the laser apparatus, it is necessary to control the laser emission wavelength of each light source element to a desired wavelength.

For example, US 2016/0111850 A discloses a laser apparatus that multiplexes laser beams having different wavelengths output from each of a plurality of semiconductor laser elements with a diffraction grating as a wavelength multiplexing element and outputs the multiplexed laser beams. In this laser apparatus, a reflector constituting an external resonator for returning a part of each laser beam to each of the semiconductor laser elements is provided at a subsequent stage of the diffraction grating. Accordingly, the laser emission wavelength of each semiconductor laser element is fixed (locked) to a desired wavelength.

Additionally, US 2016/0172823 A discloses a configuration using a volume Bragg grating (VBG) that selectively reflects light of a predetermined wavelength bandwidth as a reflector constituting an external resonator. In this configuration, the laser emission wavelength of each semiconductor laser element is locked to a reflection wavelength of VBG.

Furthermore, US 2001/0026574 A discloses a configuration in which a band pass filter that causes light of a predetermined wavelength bandwidth to selectively transmit therethrough is disposed between a semiconductor laser element and a partially transmissive reflector constituting an external resonator, and wavelength locking is performed at the transmission wavelength of the band pass filter. Here, the partially transmissive reflector is a reflector having a function of causing a part of the input light to transmit therethrough and reflecting the remaining part.

As described above, in the laser apparatus, it may be required to control the laser emission wavelength of the light source element to a desired wavelength.

### SUMMARY OF THE INVENTION

The present disclosure has been made in view of the above, and is directed to a laser apparatus capable of suitably controlling the laser emission wavelength of the light source element to a desired wavelength.

According to a first aspect of the present disclosure, there is provided a laser apparatus including a plurality of light source elements, each of which outputs a laser beam; a wavelength selecting element disposed in an optical path of each of the laser beams and configured to cause light in a predetermined wavelength band to selectively transmit therethrough; and a partially transmissive reflector disposed so as to receive the light transmitted through the wavelength selecting element and configured to reflect a part of the input light toward the wavelength selecting element and cause a remaining part to transmit therethrough, wherein the wavelength selecting element causes a part of each of the laser beams output from each of the light source elements to selectively transmit therethrough, the partially transmissive reflector reflects a part of each of the transmitted laser beams, and the wavelength selecting element causes a part of each of the reflected laser beams to transmit therethrough to return to the light source elements that have output the laser beams, and each of the light source elements preferentially oscillates at a wavelength within a wavelength bandwidth in which each of the laser beams transmits through the wavelength selecting element.

According to a second aspect of the present disclosure, there is provided a laser apparatus including a plurality of light source elements, each of which outputs a laser beam; a partially branching element disposed so as to receive each laser beam and configured to reflect and branch a part of the input light in a direction forming an angle with respect to a traveling direction of each laser beam and cause a remaining part to transmit therethrough; a wavelength selecting element disposed in a remaining optical path of each of the reflected and branched laser beams and configured to cause light in a predetermined wavelength bandwidth to transmit therethrough; and a reflector disposed so as to receive the light transmitted through the wavelength selection element and configured to reflect the input light toward the wavelength selecting element, wherein the partially branching element selectively branches a part of each of the laser beams output from each of the light source elements, the wavelength selecting element causes a part of each of the branched laser beams to selectively transmit therethrough, the reflector reflects a part of each of the transmitted laser beams toward the wavelength selecting element, the wavelength selecting element causes a part of each of the reflected laser beams to selectively transmit therethrough, the partially branching element reflects a part of each of the transmitted laser beams to return to the light source elements that have output the laser beams, and each of the light source elements preferentially oscillates at a wavelength within a wavelength bandwidth in which each of the laser beams transmits through the wavelength selecting element.

According to a third aspect of the present disclosure, there is provided a laser apparatus including a plurality of light source elements, each of which outputs a laser beam having a different wavelength; a plurality of wavelength selecting elements each disposed in an optical path of each of the laser beams and each configured to cause light in a predetermined wavelength band to selectively transmit therethrough; a plurality of partially transmissive reflectors each disposed so as to receive the light transmitted through the wavelength selecting elements, each configured to reflect a part of the input light toward the wavelength selecting elements and each configured to cause a remaining part to transmit therethrough; and a wavelength multiplexing element disposed at a subsequent stage of each of the partially transmissive reflectors to multiplex each of the laser beams, wherein each of the wavelength selecting elements causes a part of each of the laser beams output from each of the light source elements to selectively transmit therethrough, each of the partially transmissive reflectors reflects a part of each of the transmitted laser beams, each of the wavelength selecting elements causes a part of each of the reflected laser beams to transmit therethrough to return to the light source elements that have output the laser beams, and each of the light source elements preferentially oscillates at a wavelength within a wavelength bandwidth in which each of the laser beams transmits through each of the wavelength selecting elements.

According to a fourth aspect of the present disclosure, there is provided a laser apparatus including a plurality of light source elements, each of which outputs a laser beam having a different wavelength; a plurality of partially branching elements each disposed so as to receive each laser beam, each configured to reflect and branch a part of each of the input light in a direction forming an angle with respect to a traveling direction of each laser beam and cause a remaining part to transmit therethrough; a plurality of wavelength selecting elements each disposed in a remaining optical path of each of the reflected and branched laser beams and each configured to cause light in a predetermined wavelength bandwidth to transmit therethrough; a plurality of reflectors each disposed so as to receive the light transmitted through the wavelength selection elements and each configured to reflect the input light toward the wavelength selecting elements; and wavelength multiplexing elements disposed at a subsequent stage of each of the partially branching elements and configured to multiplex each of the laser beams, wherein each of the partially branching elements selectively branches a part of each of the laser beams output from each of the light source elements, each of the wavelength selecting elements selectively transmits a part of each of the branched laser beams, the reflector reflects a part of each of the transmitted laser beams toward the wavelength selecting elements, each of the wavelength selecting elements causes a part of each of the reflected laser beams to selectively transmit therethrough, each of the partially branching element reflects a part of each of the transmitted laser beams to return to the light source elements that have output the laser beams, and each of the light source elements preferentially oscillates at a wavelength within a wavelength bandwidth in which each of the laser beams transmits through the wavelength selecting elements.

According to a fifth aspect of the present disclosure, there is provided a laser apparatus including a plurality of light source modules each outputting a laser beam having a different wavelength; wavelength multiplexing elements configured to multiplex each of the laser beams; a lens disposed between the plurality of light source modules and the wavelength multiplexing elements and configured to condense each of the laser beams to the wavelength multiplexing elements; a first reflector disposed at a subsequent stage of the wavelength multiplexing elements; a second reflector disposed at a subsequent stage of the first reflector; and a gain medium disposed between the first reflector and the second reflector, wherein the gain medium is optically excited by each of the laser beams to emit light, the first reflector causes each of the laser beams to transmit thererthrough, and the first reflector and the second reflector reflect light emitted by the gain medium and constitute an optical resonator for light emitted by the gain medium.

### BRIEF DESCRIPTION OF THE DRAWINGS

FIG. 1 is a schematic configuration diagram of a laser apparatus according to a first embodiment;

FIG. 2A is a schematic configuration diagram of a main part of the laser apparatus illustrated in FIG. 1;

FIG. 2B is a schematic configuration diagram of a main part of the laser apparatus illustrated in FIG. 1;

FIG. 3A is a schematic diagram for explaining the principle of wavelength locking in the laser apparatus illustrated in FIG. 1;

FIG. 3B is a schematic diagram for explaining the principle of wavelength locking in the laser apparatus illustrated in FIG. 1;

FIG. 4A is a schematic configuration diagram of a main part of a laser apparatus according to a second embodiment;

FIG. 4B is a schematic configuration diagram of a main part of the laser apparatus according to the second embodiment;

FIG. 5 is a schematic diagram for explaining the principle of wavelength locking in the laser apparatus illustrated in FIGS. 4A and 4B;

FIG. 6A is a schematic configuration diagram of the laser apparatus according to a modification of the second embodiment;

FIG. 6B is a schematic configuration diagram of the laser apparatus according to the modification of the second embodiment;

FIG. 7 is a schematic configuration diagram of a laser apparatus according to a third embodiment;

FIG. 8 is a schematic configuration diagram of a laser apparatus according to a fourth embodiment;

FIG. 9A is a schematic configuration diagram of a main part of a laser apparatus according to a fifth embodiment;

FIG. 9B is a schematic configuration diagram of a laser apparatus according to a sixth embodiment;

FIG. 10 is a schematic configuration diagram of a laser apparatus according to a seventh embodiment;

FIG. 11 is a schematic configuration diagram of a wavelength combining module of a laser apparatus according to an eighth embodiment;

FIG. 12 is a schematic configuration diagram of an optical fiber disposing portion;

FIG. 13 is a schematic configuration diagram of another example of the optical fiber disposing portion;

FIG. 14 is a schematic configuration diagram of an output unit;

FIG. 15 is a schematic configuration diagram of a laser apparatus according to a ninth embodiment;

FIG. 16A is a schematic configuration diagram of a laser apparatus according to a tenth embodiment;

FIG. 16B is a schematic configuration diagram of a laser apparatus according to the tenth embodiment; and

FIG. 17 is a schematic diagram of a configuration in which an anamorphic optical system is provided.

### DETAILED DESCRIPTION OF THE PREFERRED EMBODIMENTS

Hereinafter, embodiments of a laser apparatus according to the present disclosure will be described in detail with reference to the drawings. It should be noted that the present disclosure is not limited by this embodiment. In each drawing, the same or corresponding elements are denoted by the same reference signs as appropriate. In addition, in the figure, a direction will be explained by appropriately using an XYZ coordinate system which is an orthogonal coordinate system of three axes (X axis, Y axis, and Z axis).

### First Embodiment

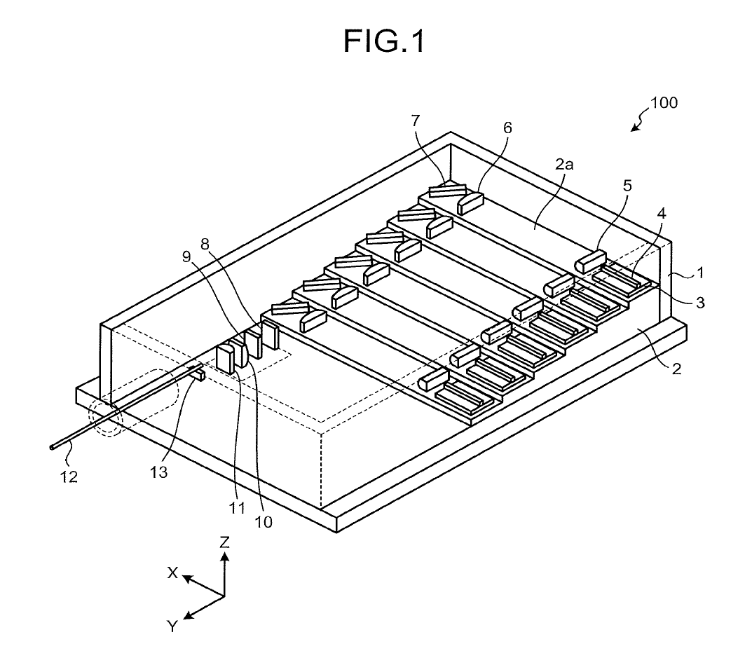

FIG. 1 is a schematic configuration diagram of a laser apparatus according to a first embodiment. A laser apparatus 100 includes a housing 1, a mounting table 2, six submounts 3, six semiconductor laser elements 4 as a light source element, six first cylindrical lenses 5, six second cylindrical lenses 6, six reflection mirrors 7, a band pass filter 8 that is a wavelength component selector that causes light having a predetermined wavelength bandwidth to selectively transmit therethrough, a partial mirror 9 that is a partially transmissive reflector, a third cylindrical lens 10, a fourth cylindrical lens 11, an optical fiber 12, an optical fiber mounting table 13, and a rotation mechanism to be described later.

The housing 1 houses components of the laser apparatus 100. The mounting table 2 is disposed on a bottom surface in the housing 1 and has six terrace-shaped mounting surfaces 2a on a surface thereof. Each of the six submounts 3 is mounted on the mounting surface 2a of the mounting table 2.

Each of the six semiconductor laser elements 4 is a multi-mode laser, is mounted on the submount 3, and outputs a laser beam in an X direction. In each semiconductor laser element 4, a low reflectance coat is formed on an end surface on a laser beam output side and a high reflectance coat is formed on a rear facet opposite to the end surface on the output side. The low reflectance coat and the high reflectance coat constitute an optical resonator. Each of the six first cylindrical lenses 5 is mounted in the X direction with respect to the semiconductor laser element 4 on the mounting surface 2a. Each of the six second cylindrical lenses 6 is mounted in the X direction with respect to the first cylindrical lens 5 on the mounting surface 2a. Each of the six reflection mirrors 7 is mounted in the X direction with respect to the second cylindrical lens 6 on the mounting surface 2a.

The band pass filter 8, the partial mirror 9, the third cylindrical lens 10, and the fourth cylindrical lens 11 are disposed in this order in a Y direction with respect to the reflection mirror 7 in the housing 1. The optical fiber 12 is a multi-mode fiber, and has one end portion inserted into the housing 1 in the Y direction of the fourth cylindrical lens 11, and mounted on the optical fiber mounting table 13.

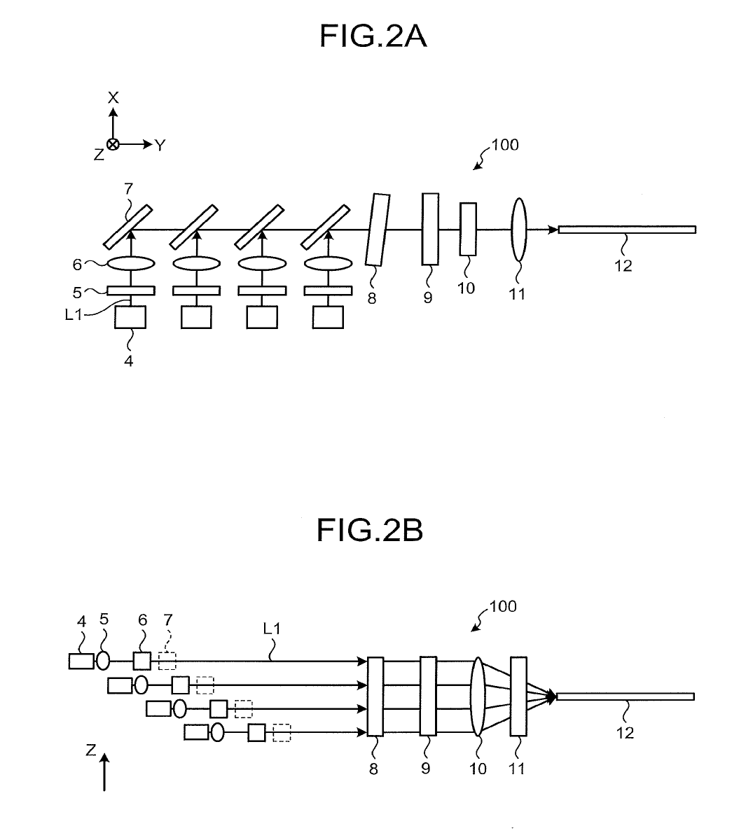

FIGS. 2A and 2B are schematic configuration diagrams of a main part of the laser apparatus 100. FIG. 2A is a view of the laser apparatus 100 as viewed in the Z direction, FIG. 2B is a view of the laser apparatus 100 as viewed from a direction perpendicular to the Z direction, and illustrates, for the sake of explanation, so that each component is arranged along an optical path output from the semiconductor laser element 4. For simplification of the drawing, the four semiconductor laser elements 4, the four first cylindrical lenses 5, the four second cylindrical lenses 6, and the four reflection mirrors 7 are only illustrated.

As illustrated in FIGS. 2A and 2B, each of the semiconductor laser elements 4 is a multi-mode laser, and outputs a wavelength locked laser beam L1 by the principle described later. The wavelength of the laser beam is, for example, in the range of 900 nm to 1100 nm, but is not particularly limited. Each of the first cylindrical lenses 5 collimates each of the laser beams L1 in the Z direction. Each of the second cylindrical lenses 6 collimates each of the laser beams L1 in the Y direction. As a result, each of the laser beams L1 becomes substantially collimated light. That is, one set of the first cylindrical lens 5 and the second cylindrical lens 6 functions as a collimating lens. The reflection mirrors 7 reflect corresponding ones of the laser beams L1 in the Y direction. Here, as illustrated in FIGS. 1 and 2B, the six semiconductor laser elements 4 are disposed so that the positions of the semiconductor laser elements 4 in the Z direction are different from each other by the mounting table 2. Therefore, the laser beam L1 output from a certain semiconductor laser element 4 is reflected by the reflection mirror 7 mounted on the same mounting surface 2a, but does not interfere with the reflection mirror 7 mounted on the other mounting surfaces 2a, and reaches the band pass filter 8.

The band pass filter 8 for wavelength locking and the partial mirror 9 are disposed in an optical path of each laser beam L1. The functions of the band pass filter 8 and the partial mirror 9 will be described in detail later. The third cylindrical lens 10 condenses each of the laser beams L1 output from the partial mirror 9 in the Z direction. The fourth cylindrical lens 11 condenses each of the laser beams L1 in the X direction and optically couples each of the laser beams L1 to the optical fiber 12. That is, one set of the third cylindrical lens 10 and the fourth cylindrical lens 11 functions as a condenser lens. The optical fiber 12 propagates each of the laser beams L1. Each of the propagated laser beams L1 is used for a desired application (laser processing or the like).

Principle of Wavelength Locking in First Embodiment

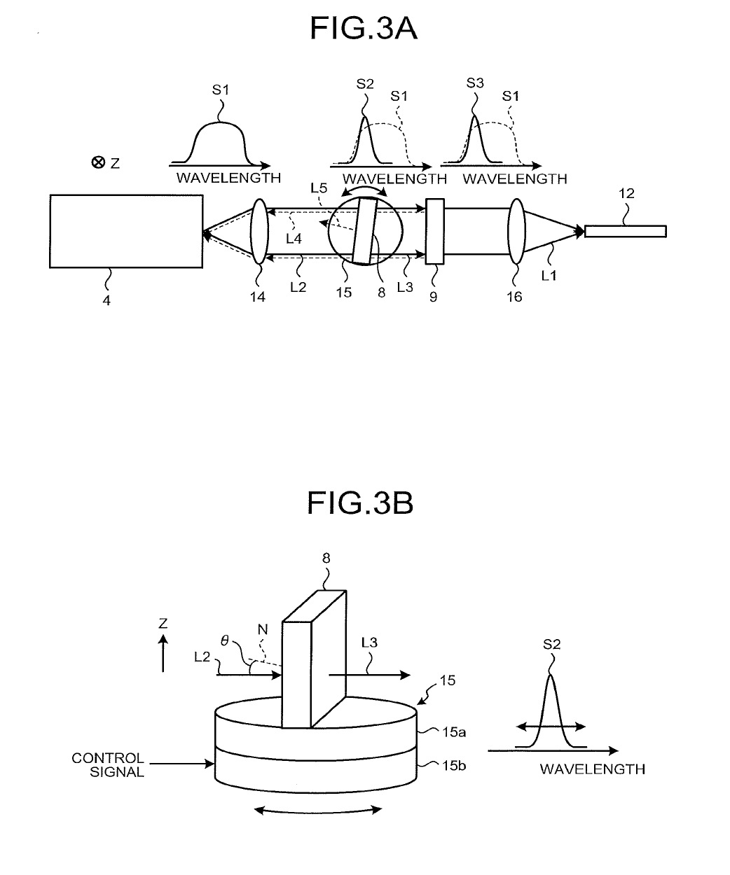

With reference to FIGS. 3A and 3B, the principle of wavelength locking in the laser apparatus 100 according to the first embodiment will be described. First, description will be made with reference to FIG. 3A. In FIG. 3A, one set of the first cylindrical lens 5 and the second cylindrical lens 6 is illustrated as a collimating lens 14. In addition, a pair of the third cylindrical lens 10 and the fourth cylindrical lens 11 is illustrated as a collimating lens 16.

The semiconductor laser element 4 outputs a laser beam L2 indicated by an output wavelength spectrum S1. The laser beam L2 output from the semiconductor laser element 4 is collimated by the collimating lens 14 and input to the band pass filter 8. The band pass filter 8 has a transmission wavelength spectrum S2 overlapping on a wavelength axis with the output wavelength spectrum S1. Therefore, the band pass filter 8 causes only a laser beam L3 to selectively transmit therethrough. The laser beam L3 is a part of the laser beam L2 and overlaps with the transmission wavelength spectrum S2. The partial mirror 9 reflects a part of the transmitted laser beam L3 as a laser beam L4. The reflected laser beam L4 again transmits through the band pass filter 8, is condensed by the collimating lens 14, returns to the semiconductor laser element 4 that has output the laser beam L2. The band pass filter 8 and the partial mirror 9 function as an external resonance end having wavelength selectivity, and function as a composite resonator by a combination of a low reflectance coat and a high reflectance coat of the semiconductor laser element 4. As a result, the semiconductor laser element 4 preferentially oscillates at a wavelength within the wavelength bandwidth in which the laser beam transmits through the band pass filter 8. As a result, the laser emission wavelength of the semiconductor laser element 4 is locked to the wavelength within the wavelength bandwidth in which the laser beam transmits through the band pass filter 8. The semiconductor laser element 4 outputs the wavelength locked laser beam L1. An output wavelength spectrum S3 indicates the output spectrum of the laser beam L1.

As illustrated in FIGS. 1, 2A and 2B, in the laser apparatus 100, since the common band pass filter 8 and the partial mirror 9 are used for the six semiconductor laser elements 4, the wavelength locking illustrated in FIG. 3A is performed for the six semiconductor laser elements 4. Accordingly, it is possible to lock the laser emission wavelengths of the six semiconductor laser elements 4 to the same wavelength all together.

Further, as illustrated in FIG. 3A, the laser apparatus 100 includes a rotation mechanism 15 that rotates the band pass filter 8 so that the laser emission wavelength of each semiconductor laser element 4 is locked to a desired wavelength. As illustrated in FIG. 3B, the rotation mechanism 15 includes a rotary table 15a on which the band pass filter 8 is mounted, and a drive mechanism 15b that rotates the rotary table 15a about an axis parallel to the Z axis. The drive mechanism 15b is controlled by a control signal input from the outside, and rotates the rotary table 15a by a desired angle.

When the band pass filter 8 is rotated, an angle (incident angle) θ between a normal line N of a light entrance surface of the band pass filter 8 and the incident laser beam L2 changes, so that the transmission wavelength spectrum S2 also moves on the wavelength axis. The transmission wavelength spectrum S2 moves to a short wavelength side when an incident angle θ is increased, and moves to a long wavelength side when the incident angle θ is decreased. Therefore, by adjusting the incident angle θ, it is possible to lock the laser emission wavelength of each semiconductor laser element 4 to a desired wavelength, and the locked wavelength can be changed within the common bandwidth among the laser emissionable wavelength bandwidths of the semiconductor laser elements 4. When there is no need to change the locked wavelength, the rotation mechanism 15 may be deleted. In this case, at the time of assembling the laser apparatus 100, the angle of the band pass filter 8 may be adjusted and fixed so that a peak wavelength of the transmission wavelength spectrum S2 becomes a desired wavelength.

Since a part of the laser beam L2 may be reflected as a laser beam L5 (FIG. 3A) by the light incident surface of the band pass filter 8 to become stray light, it is preferable to provide a processing unit that reduces the laser beam L5 in the laser apparatus 100. For example, the processing unit may use a known configuration that absorbs the laser beam L5 and converts light energy of the laser beam L5 into thermal energy.

In this laser apparatus 100, it is preferable to perform lock control of the laser emission wavelength of each semiconductor laser element 4 collectively to a desired wavelength. Furthermore, the laser apparatus 100 can be configured by merely and additionally installing the band pass filter 8, the partial mirror 9, and the rotation mechanism 15 to the laser apparatus having a configuration in which the band pass filter 8, the partial mirror 9, and the rotation mechanism 15 are absent. Since addition of such configuration hardly changes the optical path of the laser beam in the laser apparatus that has not been provided with the configuration, optical alignment is easily conducted after the addition. In addition, since the volume occupied by the additional components is relatively small, an increase in the size of the laser apparatus 100 is suppressed. When the angle of the band pass filter 8 is changed, the optical path of the laser beam is slightly shifted. When transmitting through the collimating lens 16, the optical path shift results in an angular change, but there is little adverse effect. This is because the optical fiber 12 is a multi-mode fiber and has a large core diameter and numerical aperture. Namely, with such a large core diameter and numerical aperture, a coupling loss hardly increases due to the angular change. Furthermore, by reducing the thickness of the band pass filter 8, the change in the optical path and thus the angular change can be reduced.

In addition, the band pass filter 8, if made of a dielectric multilayer coat, can be fabricated by vapor deposition, so that production costs can be reduced by collective manufacturing. Furthermore, even if there is a variation in the peak of a transmission wavelength bandwidth of the band pass filter 8, it is possible to absorb the variation of the peak by adjusting the angle of the band pass filter 8; therefore, the manufacturing yield is increased. In addition, since amplified spontaneous emission (ASE) light output from each semiconductor laser element 4 is cut by the band pass filter 8, it is possible to prevent light of an unintended wavelength from being output.

It should be noted that instead of the partial mirror 9, an output end of the optical fiber 12 may be used as a partially transmissive reflector, and light returned from the output end may be used. For example, if an antireflection coating is not provided on the output end of the optical fiber 12, 4% Fresnel reflection occurs at the boundary between glass and air. Light may be returned to each semiconductor laser element 4 from the output end by making use of such reflection. By applying the dielectric multilayer film coating to the optical fiber 12, thereby to by realize a desired reflectance, the intensity of the returning light may be adjusted. When the output end of the optical fiber is used as a reflection end, the partial mirror 9 becomes unnecessary and the alignment becomes easy.

Meanwhile, in the laser apparatus 100, an optical component for polarization-combining a laser beam from each semiconductor laser element 4 may be further provided. For example, the wavelength of a laser beam from the laser element group including the plurality of semiconductor laser elements 4 may be collectively locked, to polarization-combine the wavelength locked laser beam from the laser element group, the laser beam having an orthogonal polarization. Alternatively, the laser apparatus 100 may be configured so that the wavelength locking functions after polarization-combining of the laser beam from the laser element group, the laser beam having an orthogonal polarization.

### Second Embodiment

Next, a second embodiment will be described. The laser apparatus according to the second embodiment also includes, similar to the laser apparatus 100 according to the first embodiment, a housing, a mounting table, six submounts, six semiconductor laser elements, six first cylindrical lenses, six second cylindrical lenses, six reflection mirrors, a band pass filter, a third cylindrical lens, a fourth cylindrical lens, an optical fiber, an optical fiber mounting table, and a rotation mechanism. However, but the laser apparatus according to the second embodiment has additional components. A main difference of the laser apparatus according to the second embodiment from the laser apparatus 100 will be described below.

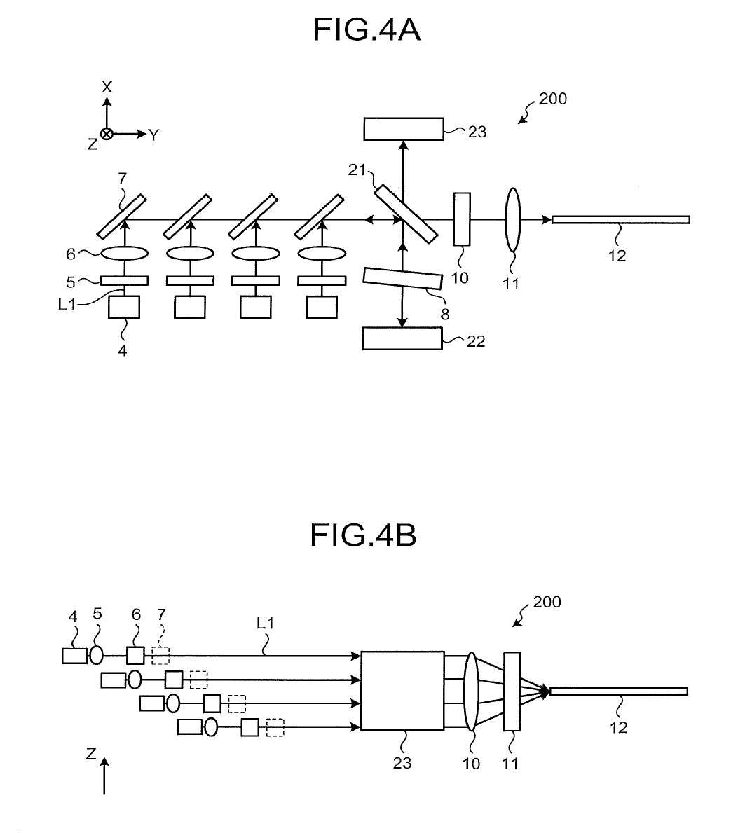

Each of FIGS. 4A and 4B is a schematic configuration diagram of a main part of a laser apparatus 200 according to the second embodiment. FIG. 4A is a view of the laser apparatus 200 as viewed in the Z direction, FIG. 4B is a view of the laser apparatus 200 as viewed from a direction perpendicular to the Z direction, and illustrates, for the sake of explanation, so that each component is arranged along an optical path output from the semiconductor laser element 4. For simplification of the drawing, the four semiconductor laser elements 4, the four first cylindrical lenses 5, the four second cylindrical lenses 6, and the four reflection mirrors 7 are only illustrated.

As illustrated in FIGS. 4A and 4B, the laser apparatus 200 includes a tap mirror 21 which is a partially branching element, a reflection mirror 22 which is a reflector, and a stray light processing unit 23 as an additional component to the laser apparatus 100.

The semiconductor laser element 4 outputs the wavelength locked laser beam L1 according to the principle described later. Each of the first cylindrical lens 5 and the second cylindrical lens 6 makes each laser beam L1 substantially collimated light. Each reflection mirror 7 reflects each laser beam L1 in the Y direction. Here, as illustrated in FIG. 4B, the laser beam L1 output from a certain semiconductor laser element 4 is reflected by the reflection mirror 7 mounted on the same mounting surface 2a (see, FIG. 1), but does not interfere with the reflection mirror 7 mounted on the other mounting surfaces 2a, and reaches the tap mirror 21.

Among the tap mirror 21, the band pass filter 8, and the reflection mirror 22 for wavelength locking, the tap mirror 21 is disposed in the optical path of each laser beam L1. The tap mirror 21 reflects and branches a part of each laser beam L1 in a direction forming an angle with respect to a traveling direction (−X direction perpendicular to a traveling direction in the present second embodiment) and causes the remaining part to transmit therethrough. The band pass filter 8 and the reflection mirror 22 are disposed in this order in a direction (−X direction in the second embodiment) in which the tap mirror 21 reflects a part of each laser beam L1 with respect to the tap mirror 21. The stray light processing unit 23 is disposed on the opposite side of the band pass filter 8 with the tap mirror 21 interposed therebetween. The third cylindrical lens 10 and the fourth cylindrical lens 11 optically couple each of the laser beams L1 to the optical fiber 12 as a condensing lens. The optical fiber 12 propagates each of the laser beams L1. Each of the propagated laser beams L1 is used for a desired a.

Principle of Wavelength Locking in Second Embodiment

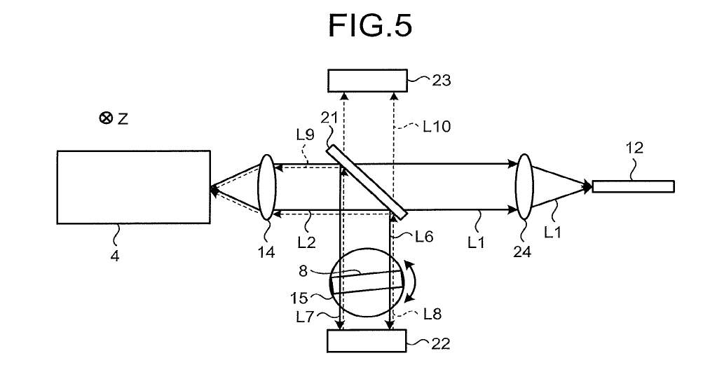

With reference to FIGS. 5 and 3A, the principle of wavelength locking in the laser apparatus 200 according to the second embodiment will be described. In FIG. 5, the third cylindrical lens 10 and the fourth cylindrical lens 11 are illustrated as a condensing lens 24.

The semiconductor laser element 4 outputs the laser beam L2 indicated by the output wavelength spectrum S1 (see FIG. 3A). The laser beam L2 output from the semiconductor laser element 4 is collimated by the collimating lens 14 and input to the tap mirror 21. The tap mirror 21 reflects and branches a part of the laser beam L2 as a laser beam L6 (FIG. 5A) toward the band pass filter 8, and causes the remaining part to transmit therethrough. The band pass filter 8 has a transmission wavelength spectrum S2 overlapping with the output wavelength spectrum S1 on a wavelength axis. Therefore, the band pass filter 8 causes only a laser beam L7 to selectively transmit therethrough. The laser beam L7 is a part of the laser beam L6 and overlaps with the transmission wavelength spectrum S2. The reflection mirror 22 receives the transmitted laser beam L7 and reflects the transmitted laser beam L7 as a laser beam L8 toward the band pass filter 8. The reflected laser beam L8 again transmits selectively through the band pass filter 8 and reaches the tap mirror 21. The tap mirror 21 reflects and branches a part of the laser beam L2 as a laser beam L9 toward the collimating lens 14, and causes the remaining part to transmit therethrough as a laser beam L10. The laser beam L9 is condensed by the collimating lens 14 and returned to the output semiconductor laser element 4. As described above, the band pass filter 8 and the reflection mirror 22 function as an external resonance having wavelength selectivity, and the laser emission wavelength of the semiconductor laser element 4 is locked to a wavelength within the wavelength bandwidth in which the laser beam transmits through the band pass filter 8. The semiconductor laser element 4 outputs the wavelength locked laser beam L1.

As illustrated in FIGS. 4A and 4B, in the laser apparatus 200, since the common band pass filter 8 and the reflection mirror 22 are used for the six semiconductor laser elements 4, the laser emission wavelengths of the six semiconductor laser elements 4 can be collectively locked to the same wavelength.

Further, as illustrated in FIG. 5, the laser apparatus 200 also includes the rotation mechanism 15 that rotates the band pass filter 8. Accordingly, it is possible to lock the laser emission wavelength of each semiconductor laser element 4 to a desired wavelength, and the locked wavelength can be changed within the common bandwidth among the laser emissionable wavelength bandwidths of the semiconductor laser elements 4. When there is no need to change the locked wavelength, the rotation mechanism 15 may be deleted.

The stray light processing unit 23 may prevent the laser beam L10 transmitted through the tap mirror 21 from becoming stray light.

In this laser apparatus 200, it is preferable to perform a lock control of the laser emission wavelength of each semiconductor laser element 4 collectively to a desired wavelength. Furthermore, the laser apparatus 200 can be configured by merely and additionally installing the tap mirror 21, the band pass filter 8, the reflection mirror 22, and the rotation mechanism 15 to the laser apparatus having a configuration in which the tap mirror 21, the band pass filter 8, the reflection mirror 22, and the rotation mechanism 15 are absent. Since addition of such configuration hardly changes the optical path of the laser beam in the laser apparatus that has not been provided with the configuration, optical alignment is easily conducted after the addition. In addition, since the volume occupied by the additional components is relatively small, an increase in the size of the laser apparatus 200 is suppressed. Particularly, in the laser apparatus 200, a part of the laser beam L1 is guided to the outside of the optical path of the laser beam L1 by the tap mirror 21, and the wavelength is locked by the band pass filter 8 and the reflection mirror 22. Therefore, since only the tap mirror 21 is required for a component disposed in the optical path of the laser beam L1, even if a distance between the collimating lens 14 and the condensing lens 24 is small, the additional components can be easily mounted. In addition, in the laser apparatus 200, since an output direction of the laser beam L10, which may be stray light, can be set in a direction perpendicular to the optical path of the laser beam L1, there can be an enough space for the stray light processing unit 23 to be disposed. Therefore, stray light can be effectively suppressed.

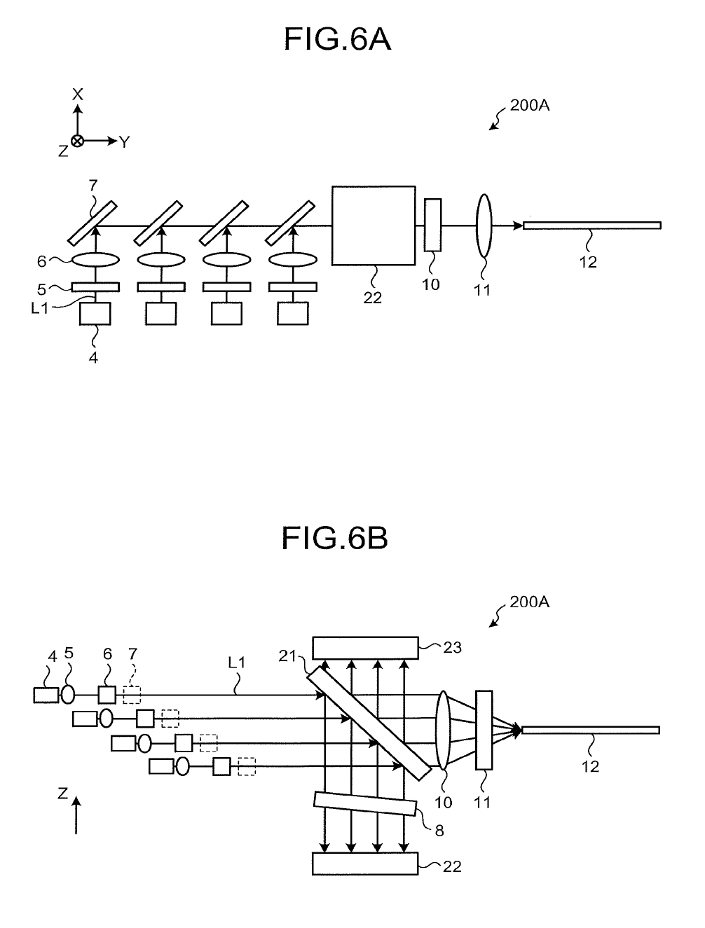

In the second embodiment, the band pass filter 8 and the reflection mirror 22 are disposed in the −X direction with respect to the tap mirror 21, but the band pass filter 8 and the reflection mirror 22 may be disposed in a +X direction. Further, as in a laser apparatus 200A according to the modification of the second embodiment illustrated in FIGS. 6A and 6B, the band pass filter 8 and the reflection mirror 22 may be disposed in the −Z direction with respect to the tap mirror 21 or may be disposed in the +Z direction.

In the laser apparatuses 100 and 200 according to the first and second embodiments, a polarization combining component may be provided. Polarization combining may be performed after collectively locking the wavelength of the laser beam of each polarization or may be configured so that wavelength locking functions after polarization combining.

### Third Embodiment

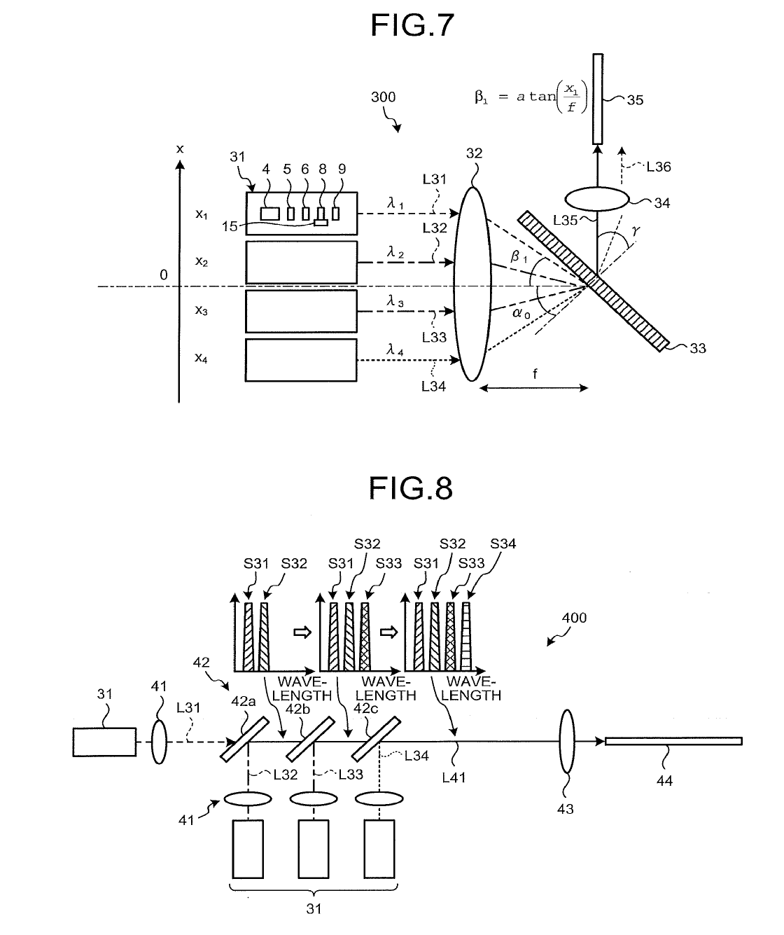

FIG. 7 is a schematic configuration diagram of a laser apparatus according to a third embodiment. The laser apparatus 300 includes four laser modules 31, a lens 32, a transmission type diffraction grating 33 as a wavelength multiplexing component, a lens 34, and an optical fiber 35 as a multi-mode fiber.

Each laser module 31 includes a semiconductor laser element 4, a first cylindrical lens 5, a second cylindrical lens 6, a band pass filter 8, a partial mirror 9, and a rotation mechanism 15. Thus, in each laser module 31, the band pass filter 8 causes a part of each laser beam output from each semiconductor laser element 4 to selectively transmit therethrough, each partial mirror 9 reflects a part of each of the transmitted laser beams, each band pass filter 8 causes a part of each of the reflected laser beams to transmit therethrough and returns the part to each semiconductor laser element 4, so that the laser emission wavelength of each semiconductor laser element 4 is locked to a wavelength within the wavelength bandwidth in which each of the laser beams transmits through the band pass filter 8. That is, in each laser module 31, wavelength locking is realized by the same principle as in the first embodiment.

However, in the laser apparatus 300, each semiconductor laser element 4 outputs laser beams each having a different wavelength. The wavelength bandwidth selectively transmitted by each band pass filter 8 also corresponds to the wavelength of the laser beam output from the corresponding semiconductor laser element 4. As a result, each of the laser modules 31 outputs laser beams L31, L32, L33, and L34 having different wavelengths λ₁, λ₂, λ₃, and λ₄ (λ₁>λ₂>λ₃>λ₄). Here, as illustrated in FIG. 7, a direction in which the laser modules 31 are arranged is an X axis. While the laser beams L31, L32, L33, and L34 travel in a direction perpendicular to the X axis, X coordinates of the respective optical paths are X₁, X₂, X₃, and X₄. X₁, X₂>0, X₃, X₄<0.

The lens 32 is disposed at the subsequent stage of each partial mirror 9 so that a focal length is f, an optical axis is perpendicular to the X axis, and the X coordinate is zero. The lens 32 condenses the laser beams L31, L32, L33, and L34 on the diffraction grating 33. The diffraction grating 33 is disposed at the subsequent stage of each partial mirror 9 and at the subsequent stage of the lens 32, and diffracts the laser beams L31, L32, L33, and L34.

Here, if the angle formed by the laser beam L31 of the wavelength λ₁ condensed on the diffraction grating 33 and the optical axis of the lens 32 is β₁, the following equation is satisfied: β₁=a tan(X₁/f). Similarly, if an angle formed between a laser beam of a wavelength λₙ (n=2, 3, and 4) and the optical axis of the lens 32 is βₙ, the following equation is satisfied: βₙ=a tan (Xₙ/f). Assuming that an angle formed by the optical axis of the lens 32 and the normal line to the principal surface of the diffraction grating 33 is α₀, a pitch of the diffraction grating 33 is Λ, a diffraction angle from the diffraction grating 33 is γ, and a diffraction order is 1,

by adjusting the laser emission wavelength of each laser module 31 and the positions of the optical paths of the laser beams L31, L32, L33, and L34 so as to satisfy the following equation:

sin(α₀+βₙ)−sin γ=sin(α₀+a tan (Xₙ/f))−sin γ=λₙ/Λ,

each of the diffraction angles of the first order diffracted beams of the laser beams L31, L32, L33, and L34 are γ. Therefore, the laser beams L31, L32, L33, and L34 are wavelength-multiplexed by the diffraction grating 33. The lens 34 optically couples the multiplexed laser beam L35 to the optical fiber 35.

In this laser apparatus 300, the laser emission wavelength of each semiconductor laser element 4 in each laser module 31 is accurately locked to a desired wavelength. Specifically, the wavelengths λ₁, λ₂, λ₃, and λ₄ of the respective laser beams L31, L32, L33, and L34 are precisely controlled (for example, in the range of 0.2 nm) to this wavelength. As a result, it is prevented that the wavelengths of the laser beams L31, L32, L33, and L34 are shifted and the laser beams L31, L32, L33, and L34 are diffracted by the diffraction grating 33 like the laser beam L36 thereby failing to couple to the optical fiber 35. That is, in the laser apparatus 300, it is preferable to wavelength-multiplex the laser beams L31, L32, L33, and L34 from the semiconductor laser elements 4 controlled to different laser emission wavelengths.

In addition, in the laser apparatus 300, a laser beam of which wavelength is different from that of a laser beam that should have returned to each semiconductor laser element 4 is returned due to crosstalk, and locking with an unintended wavelength is prevented. When an unintentional locked wavelength is reached, the laser beam is not multiplexed by the diffraction grating 33, which is a problem. Incidentally, in US 2016/0111850 A, a locking arm having an aperture is provided to suppress an unintentional locked wavelength due to such crosstalk. However, in this case, if it is attempted to transmit only the laser beam of the desired wavelength through the aperture, the locking arm becomes longer and an optical system becomes larger, which is not suitable for miniaturization.

### Fourth Embodiment

FIG. 8 is a schematic configuration diagram of a laser apparatus according to a fourth embodiment. A laser apparatus 400 includes the four laser modules 31, four lenses 41, a wavelength multiplexer 42 as a wavelength multiplexing component, a lens 43, and an optical fiber 44 as a multi-mode fiber.

In each laser module 31, wavelength locking is realized based on the same principle as in the first embodiment, and laser beams L31, L32, L33, and L34 having λ₁, λ₂, λ₃, and λ₄ having different wavelengths are output. Each lens 41 substantially collimates the laser beams L31, L32, L33, and L34.

The wavelength multiplexer 42 includes short wavelength pass filters 42a, 42b, and 42c. The short wavelength pass filters 42a, 42b, and 42c are filters that cause light having a wavelength shorter than a predetermined wavelength to transmit therethrough with low loss and reflect light of long wavelength with low loss. The short wavelength pass filters 42a, 42b, and 42c multiplex the respective laser beams L31, L32, L33, and L34 in order as a wavelength multiplexing filter. Specifically, the short wavelength pass filter 42a multiplexes the laser beams L31 and L32 by transmitting the laser beam L31 and reflecting the laser beam L32. Spectra S31 and S32 indicate spectra of the laser beams L31 and L32, respectively. Subsequently, the short wavelength pass filter 42b multiplexes the laser beams L31, L32, and L33 by transmitting the laser beam L31 and L32 and reflecting the laser beam L33. A spectrum S33 indicates the spectrum of the laser beam L33. The short wavelength pass filter 42c multiplexes the laser beams L31, L32, L33, and L34 by transmitting the laser beam L31, L32, and L33 and reflecting the laser beam L34. The spectrum S34 indicates the spectrum of the laser beam L34.

In this manner, a laser beam L41 is generated by being multiplexed by the wavelength multiplexer 42. The lens 43 condenses the laser beam L41 and optically couples the laser beam L41 to the optical fiber 44.

In this laser apparatus 400, the laser emission wavelength of each semiconductor laser element 4 in each laser module 31 is accurately locked to a desired wavelength. Specifically, the wavelengths λ₁, λ₂, λ₃, and λ₄ of the respective laser beams L31, L32, L33, and L34 are precisely controlled (for example, in the range of 0.2 nm) to this wavelength. As a result, the wavelengths of the laser beams L31, L32, L33, and L34 are shifted, so that it is prevented that excessive loss is caused by any of the short wavelength pass filters 42a, 42b, and 42c. Furthermore, since the wavelengths of the laser beams L31, L32, L33, and L34 can be changed by the rotation mechanism 15, a wavelength interval between the laser beams L31, L32, L33, and L34 can be made narrower or wider. In addition, in the laser apparatus 400, it is preferable to wavelength-multiplex the laser beams L31, L32, L33, and L34 controlled to different laser emission wavelengths.

In the laser apparatus 400, the wavelength multiplexer 42 includes three wavelength combining filters (short wavelength pass filters 42a, 42b, and 42c) in order to multiplex the four laser beams L31, L32, L33, and L34; however, in order to multiplex the two laser beams, only one wavelength multiplexer is sufficient. That is, in order to multiplex a plurality of laser beams, the wavelength multiplexer needs to include at least one wavelength multiplexing filter. As a wavelength multiplexing filter, a long wavelength pass filter or a band pass filter may be used in place of the short wavelength pass filter. In the laser apparatuses 300 and 400 of the third and fourth embodiments, instead of the laser module 31, a laser module including the semiconductor laser element 4, the first cylindrical lens 5, the second cylindrical lens 6, the tap mirror 21, the band pass filter 8, the reflection mirror 22, and the rotation mechanism 15, and configured to realize wavelength locking according to the same principle as that of the second embodiment may be used. Thus, in each laser module, each tap mirror 21 branches a part of each laser beam output from each semiconductor laser element 4, each band pass filter 8 causes a part of each of the branched laser beams to selectively transmit therethrough, each reflection mirror 22 reflects a part of each of the transmitted laser beams toward each band pass filter 8, each band pass filter 8 causes a part of each of the reflected laser beams to selectively transmit therethrough, and each tap mirror 21 reflects a part of each of the transmitted laser beams and returns the part to the output semiconductor laser elements 4 so that the laser emission wavelength of each semiconductor laser element 4 is locked to a wavelength within the wavelength bandwidth in which each of the laser beams transmits through each band pass filter 8. That is, in each laser module, wavelength locking is realized by the same principle as in the second embodiment.

### Fifth and Sixth Embodiments

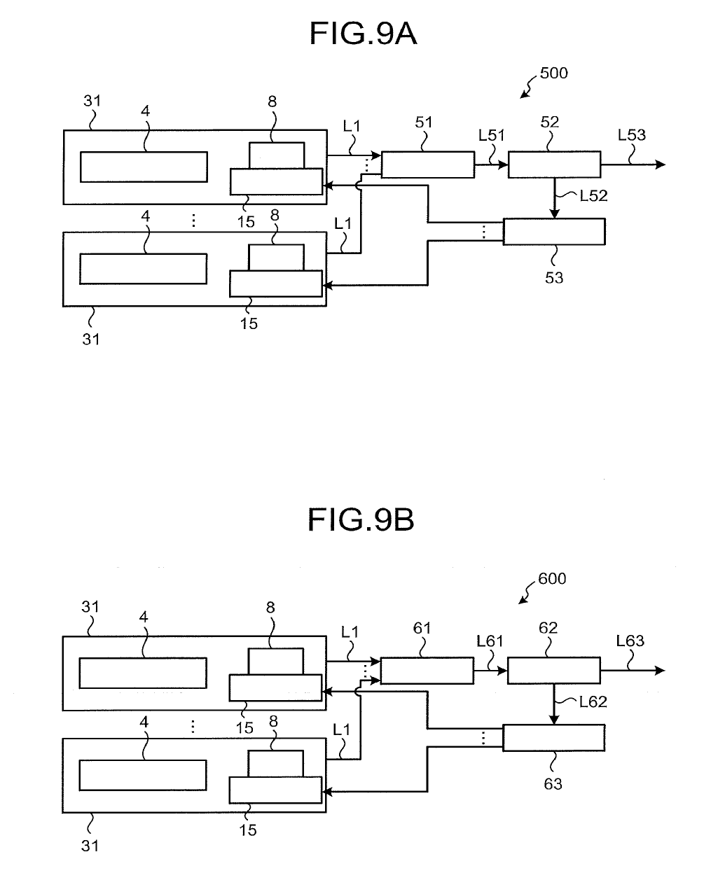

Each of FIGS. 9A and 9B is a schematic configuration diagram of a main part of a laser apparatus according to each of a fifth and sixth embodiment. FIG. 9A illustrates a laser apparatus 500 according to the fifth embodiment, and FIG. 9B illustrates a laser apparatus 600 according to the sixth embodiment.

First, the laser apparatus 500 will be described. The laser apparatus 500 includes a plurality of (three or more in the present embodiment) laser modules 31, a wavelength multiplexer 51 as a wavelength multiplexing component, an optical splitter 52, and a controller 53 having a power monitor.

Each of the laser modules 31 outputs the laser beams L1 each having a different wavelength. The wavelength multiplexer 51 includes a plurality of short wavelength pass filters, for example, like the wavelength multiplexer 42 according to the fourth embodiment, and multiplexes each of the laser beams L1 to output the multiplexed laser beam as a laser beam L51. The optical splitter 52 includes, for example, a tap mirror, reflects and branches a part of the laser beam L51 as a laser beam L52, and causes the remaining part to transmit therethrough as a laser beam L53. The wavelength multiplexer 51 may use a diffraction grating, for example.

The controller 53 includes a photoelectric element, an A/D converter, and a microcomputer. The photoelectric element is, for example, a photodiode, receives the laser beam L52 and outputs a current signal corresponding to the power to the A/D converter. The A/D converter converts a current signal which is an analog signal into a digital signal and outputs the digital signal to the microcomputer. The microcomputer performs predetermined arithmetic processing using the input digital signal and the program and data stored therein and outputs the generated control signal to the rotation mechanism 15 of each laser module 31. Each rotation mechanism 15 rotates according to a control signal, and accordingly, each band pass filter 8 also rotates. The laser emission wavelength of each semiconductor laser element 4 has a wavelength corresponding to the transmission wavelength bandwidth of each band pass filter 8.

In the laser apparatus 500, the controller 53 outputs a control signal to each rotation mechanism 15 so that the power of the received laser beam L52 is maximized. Thus, in the laser apparatus 500, the laser emission wavelength of each semiconductor laser element 4 is feedback-controlled so that the power of the output laser beam L53 becomes maximum.

Next, the laser apparatus 600 will be described. The laser apparatus 600 includes a plurality of (three or more in the present embodiment) laser modules 31, a wavelength multiplexer 61 as a wavelength multiplexing component, an optical splitter 62, and a controller 63 having a spectrum monitor.

Each of the laser modules 31 outputs the laser beams L1 each having a different wavelength. The wavelength multiplexer 61 includes a plurality of short wavelength pass filters, for example, like the wavelength multiplexer 42, and multiplexes the respective laser beam L1 to output the multiplexed laser beam as a laser beam L61. The optical splitter 62 includes, for example, a tap mirror, reflects and branches a part of the laser beam L61 as a laser beam L62, and causes the remaining part to transmit therethrough as a laser beam L63. The wavelength multiplexer 51 may use a diffraction grating, for example.

The controller 63 includes a spectrum monitor and a microcomputer. The spectrum monitor is configured to receive the laser beam L62 and acquire information on a spectral waveform of the laser beam L62. This spectral waveform contains information on the wavelength of each laser beam L1. The spectrum monitor outputs a data signal including information on the spectrum waveform to the microcomputer. The microcomputer performs predetermined arithmetic processing using the input data signal and the program and data stored therein and outputs the generated control signal to the rotation mechanism 15 of each laser module 31. Each rotation mechanism 15 rotates according to a control signal, and accordingly, each band pass filter 8 also rotates. The laser emission wavelength of each semiconductor laser element 4 has a wavelength corresponding to the transmission wavelength bandwidth of each band pass filter 8.

In the laser apparatus 600, the controller 63 outputs a control signal to each rotation mechanism 15 so that the wavelength of each laser beam L1 becomes a desired laser emission wavelength. Thus, in the laser apparatus 600, the laser emission wavelength of each semiconductor laser element 4 is feedback-controlled so as to have a desired wavelength.

In the third to sixth embodiments, the wavelength locking is realized by each laser module 31 on the same principle as that of the first embodiment, but the wavelength locking may be realized by the same principle as in the second embodiment. In this case, each laser module does not include a partial mirror but is configured to include a tap mirror, a band pass filter, and a reflection mirror.

### Seventh Embodiment

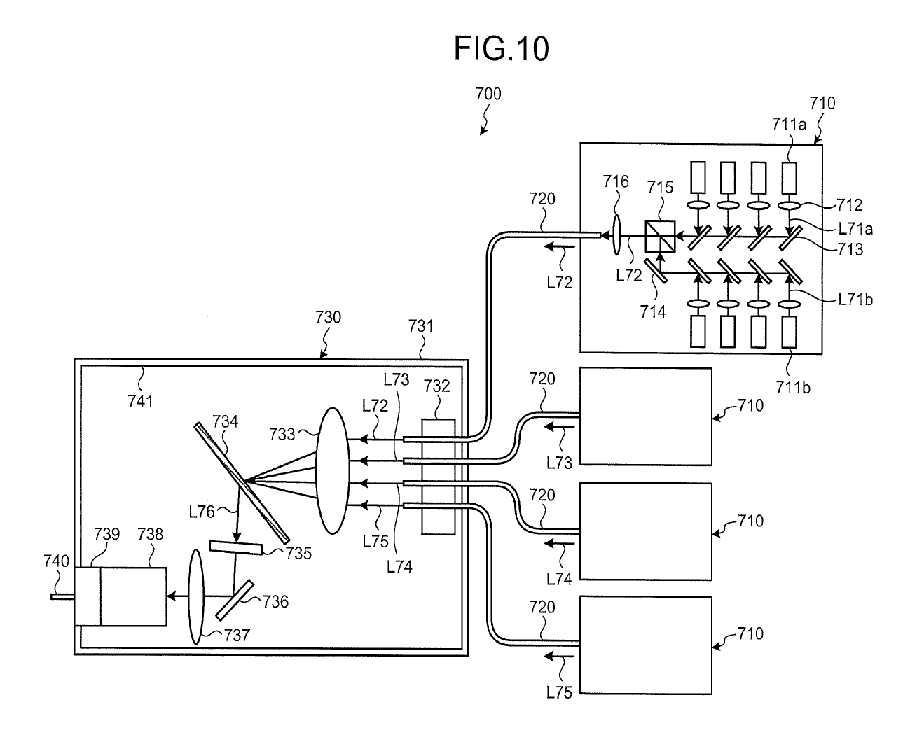

FIG. 10 is a schematic configuration diagram of a laser apparatus according to a seventh embodiment. A laser apparatus 700 according to the seventh embodiment includes four laser modules 710 as light source modules, four optical fibers 720, and a wavelength combining module 730.

Each of the laser modules 710 has, similar to a configuration of the semiconductor laser element 4, four semiconductor laser elements 711a and four semiconductor laser elements 711b, eight collimating lenses 712, eight reflection mirrors 713, a reflection mirror 714, a polarization combiner 715, and a condensing lens 716.

First, focusing on the laser module 710, explanation will be given. Each of the four semiconductor laser elements 711a outputs a laser beam L71a of linearly polarized waves having the same wavelength and the same direction. Each of the four semiconductor laser elements 711b outputs a laser beam L71b of linearly polarized waves having the same wavelength and the same direction. Each of the collimating lenses 712 substantially collimates each of the laser beams L71a and each of the laser beams L71b. Each of the reflection mirrors 713 reflects each of the laser beams L71a and each of the laser beams L71b in the same direction. Here, as in the case of the first embodiment, since the semiconductor laser elements 711a are disposed so that the heights of the semiconductor laser elements 711a are different from each other, and the semiconductor laser elements 711b are disposed so that the heights of the semiconductor laser elements 711a are different from each other; therefore, the reflected laser beams L71a and the respective laser beams L71b do not interfere with the reflection mirror 713 other than the reflected reflection mirror 713.

Each of the laser beams L71a is input to the polarization combiner 715. Each of the laser beams L71b is reflected by the reflection mirror 714 and input to the polarization combiner 715. The polarization combiner 715 polarization-combines each of the laser beams L71a and each of the laser beams L71b, and outputs the polarization-combined laser beam as the laser beam L72. The condensing lens 716 optically couples the laser beam L72 to the optical fiber 720 and outputs the coupled laser beam L72 from the laser module 710.

Here, the laser beams output from the respective laser modules 710 have different wavelengths, so that the laser beams are respectively referred to as laser beams L72, L73, L74, and L75 for distinction. The optical fibers 720 transmit the corresponding laser beams L72, L73, L74, and L75 to the wavelength combining module 730.

The wavelength combining module 730 includes a housing 731, an optical fiber disposing portion 732, a condensing lens 733, a transmission type diffraction grating 734 as a wavelength multiplexing component, a partial mirror 735, an alignment mirror 736, a condensing lens 737, an output unit 738, a light shielding cover 739, an output optical fiber 740, and a light absorption layer 741.

The housing 731 houses a component of the wavelength combining module 730. In addition, to the wavelength combining module 730, a front end of each of the optical fibers 720, from which each of the laser beams L72, L73, L74, and L75 is emitted out, is introduced. The optical fiber disposing portion 732 arranges the introduced optical fibers 720 in an array so as to be parallel to each other.

The condensing lens 733 is disposed between each laser module 710 and the diffraction grating 734, and condenses the laser beams L72, L73, L74, and L75 output from each of the optical fibers 720 onto the diffraction grating 734.

Here, as in the third embodiment, an angle formed by an optical axis of the condensing lens 733 and a normal line to the principal surface of the diffraction grating 734, a pitch of the diffraction grating 734, and a wavelength (laser emission wavelength) of each of the laser beams L72, L73, L74, and L75 and a positional relationship of the optical path are adjusted. Diffraction angles of first-order diffracted light beams of the laser beams L72, L73, L74, and L75 coincide with each other. Therefore, the laser beams L72, L73, L74, and L75 are multiplexed by the diffraction grating 734 and become a laser beam L76.

The partial mirror 735 is disposed so that the laser beam L76 is vertically reflected, and reflects a part of the laser beam L76 to the diffraction grating 734. The reflected laser beam is split into wavelength components of the laser beams L72, L73, L74, and L75 by the diffraction grating 734 due to the reciprocity of light, and returns to the semiconductor laser elements 711a and 711b of the output laser module 710. For example, the reflected laser beam split into the wavelength component of the laser beam L72 returns to the semiconductor laser elements 711a and 711b which has output the laser beam L72. Thereby, the partial mirror 735 functions as an external resonance end in combination with a high reflectance coat of the semiconductor laser elements 711a and 711b. As a result, the laser emission wavelengths of the semiconductor laser elements 711a and 711b are locked to the wavelength of the reflected and returned laser beam. As a result, the wavelengths of the laser beams L72, L73, L74, and L75 are also locked, and the wavelength is stabilized.

The alignment mirror 736 reflects the laser beam L76 output from the partial mirror 735 toward the condensing lens 737. The condensing lens 737 condenses the laser beam L76 via the output unit 738 and optically couples the laser beam L76 to the output optical fiber 740. The output optical fiber 740 is a multi-mode fiber, and outputs the multiplexed high power laser beam L76.

It is to be noted that the light shielding cover 739 is provided to prevent unnecessary light such as stray light from being output to the outside. In addition, the light absorption layer 741 is provided on the inner surface of the housing 731 and is a layer or a plating layer subjected to a light absorbing surface treatment. The light absorption layer 741 absorbs unnecessary light such as stray light, thereby preventing heat generation at an unintended place.

Since the laser apparatus 700 includes the partial mirror 735 for wavelength lock and the alignment mirror 736 for aligning the optical path to the output optical fiber 740 of the laser beam L76 in a separated manner, the optical path can be easily aligned while suitably realizing wavelength locking, thereby realizing easy assembly.

### Eighth Embodiment

Next, a laser apparatus according to an eighth embodiment will be described. Since the laser apparatus according to the eighth embodiment differs from the laser apparatus according to the seventh embodiment only in the configuration of the wavelength combining module, the configuration of the wavelength combining module will be described below.

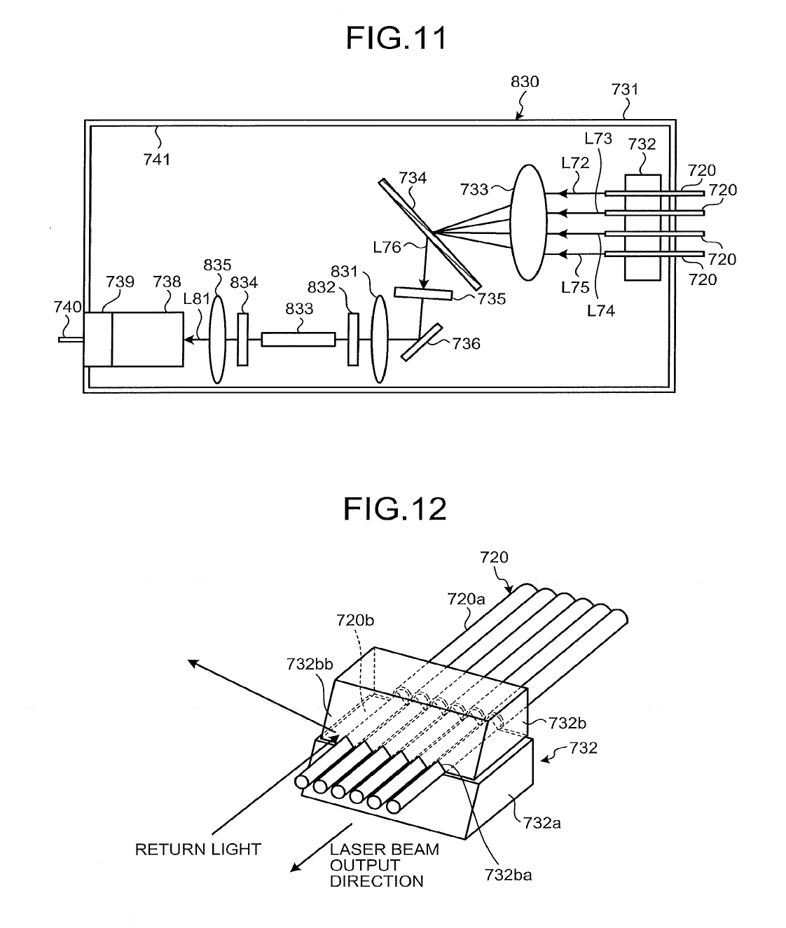

FIG. 11 is a schematic configuration diagram of a wavelength combining module of the laser apparatus according to the eighth embodiment. A wavelength combining module 830 is configured by deleting the condensing lens 737 from the wavelength combining module 730 of the laser apparatus 700 according to the seventh embodiment, d and adding a collimating lens 831, a reflection mirror 832 as a first reflector, a gain medium 833, a reflection mirror 834 as a second reflector, and a condensing lens 835 to the wavelength combining module 730. The added components will be mainly described below. In the configuration of the eighth embodiment, the collimating lens 831 is added. However, the collimating lens 831 may not be added because the collimating lens 831 is not an indispensable element.

The collimating lens 831 is disposed at a subsequent stage of the diffraction grating 734. The reflection mirror 832 is disposed at a subsequent stage of the collimating lens 831. The reflection mirror 834 is disposed at a subsequent stage of the reflection mirror 832. The gain medium 833 is disposed between the reflection mirror 832 and the reflection mirror 834. The condensing lens 835 is disposed at a subsequent stage of the reflection mirror 834.

The collimating lens 831 outputs the laser beam L76 reflected by the alignment mirror 736 to the reflection mirror 832 as substantially collimated light. The reflection mirror 832 transmits the laser beam L76.

The gain medium 833 has a characteristic of being optically excited by the laser beam L76 to emit light. The reflection mirror 832 and the reflection mirror 834 reflect light emitted by the gain medium 833 and constitute an optical resonator with respect to light emitted by the gain medium 833. As a result, the light emitted from the gain medium 833 oscillates, and the laser beam L81 generated by this oscillation is output from the reflection mirror 834 to a condensing lens 835 side.

Subsequently, the condensing lens 835 condenses the laser beam L81 via the output unit 738 and optically couples the laser beam L81 to the output optical fiber 740. The output optical fiber 740 outputs the laser beam L81.

Here, the characteristics of the laser beam L76, the reflection mirror 832, the gain medium 833, and the reflection mirror 834, each of which is used for causing the laser beam L81 to oscillate are exemplified. The laser beam L76 is obtained by combining the laser beams L72, L73, L74 and L75, but the wavelengths of the laser beams L72, L73, L74 and L75 are in the range of 900 nm to 980 nm, for example, around 940 nm. In this case, the reflection mirror 832 has a characteristic of transmitting light in the wavelength range of 900 nm to 980 nm. The gain medium 833 is, for example, an Yb:YAG rod formed in a ceramic. In this case, the gain medium 833 is optically excited by the laser beam L76 and emits light in a wavelength band including a wavelength of 1030 nm.

Furthermore, in the above case, the reflection mirror 832 has a characteristic of reflecting light having a wavelength of 1030 nm with a reflectance of 95% or more. Furthermore, it is assumed that the reflection mirror 834 reflects light having a wavelength of 1030 nm with a reflectance of about 10% and transmits light having a wavelength range of 900 nm to 980 nm. As a result, the laser beam L81 oscillates at a wavelength of 1030 nm. Note that the reflection mirror 834 may have a reflectance with no wavelength dependence such that light having a wavelength of 1030 nm and light in a wavelength range of 900 nm to 980 nm is reflected with a reflectance of about 10% and the remaining part of the light is transmitted.

In the laser apparatus according to the eighth embodiment, the laser beam L81 having high power can be output from the optical resonator formed by the gain medium 833 and the reflection mirrors 832 and 834 optically excited by the combined laser beam L76 having high power.

In the seventh and eighth embodiments, the number of the laser modules 710 is four, but there is no particular limitation as long as the number of the laser modules 710 is plural.

Configuration Example of Optical Fiber Disposing Portion

Next, a configuration example of an optical fiber disposing portion that can be used for the laser apparatus according to the seventh and eighth embodiments will be described. FIG. 12 is a schematic configuration diagram of the optical fiber disposing portion. The optical fiber disposing portion 732 includes a base portion 732a and a holding portion 732b. In FIG. 12, the number of laser modules 710 is six, and correspondingly there are six optical fibers 720.

The base portion 732a has a cooling structure such as air cooling or water cooling. The holding portion 732b is disposed on the upper surface of the base portion 732a. A plurality of V grooves 732ba is formed in an array on the bottom surface of the holding portion 732b. In each optical fiber 720, a coating 720a is removed and a glass portion 720b is exposed on a laser beam output side. Each optical fiber 720 is sandwiched between the V groove 732ba of the holding portion 732b and the upper surface of the base portion 732a in the exposed glass portion 720b and is fixed by bonding the holding portion 732b and the base portion 732a with an adhesive.

Further, a high reflectance coat is formed on a front surface 732bb of the holding portion 732b, and is inclined in a predetermined direction as described later.

In each optical fiber 720, since the coating 720a is removed and the glass portion 720b is exposed, a laser beam in a cladding mode leaks, and the optical fiber disposing portion 732 is heated. However, since the base portion 732a has a cooling structure, excessive temperature rise of the optical fiber disposing portion 732 is prevented.

As described in the seventh embodiment, a part of the laser beam is returned to the laser module 710 as return light by the partial mirror 735. At this time, there is a case where the return light does not couple to the optical fiber 720 and reaches the front surface 732bb of the optical fiber disposing portion 732 located around the optical fiber 720. However, such return light is reflected in a direction perpendicular to an extending direction of each optical fiber 720 because the high reflectance coat is formed on the front surface 732bb and the front surface 732bb is inclined. This prevents the returned light from becoming stray light and adversely affecting the operation of the laser apparatus.

In the optical fiber disposing portion 732, a light shielding film may be provided on the front surface 732bb of the holding portion 732b instead of the high reflectance coat to prevent return light from becoming stray light. In this case, the light shielding film may include, for example, a light-absorbing film. When the light shielding film is provided, the front surface 732bb may not be inclined.

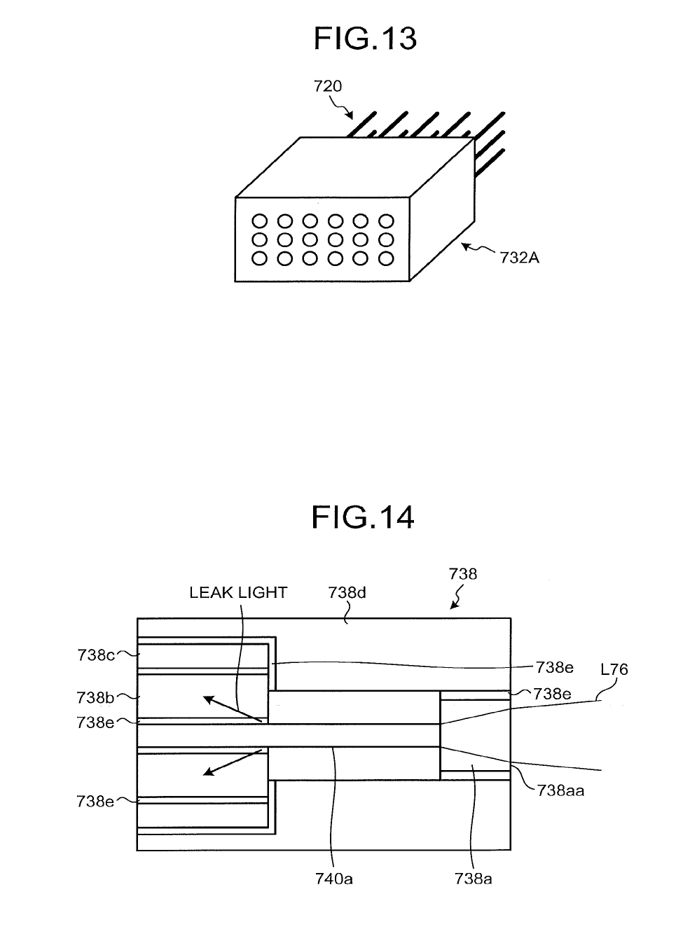

FIG. 13 is a schematic configuration diagram of another example of the optical fiber disposing portion. The optical fiber disposing portion 732A is configured so that the optical fibers 720 can be arranged in a two-dimensional array. The optical fiber disposing portion 732A can be formed using a molded product of a multicore capillary or an MT ferrule. Also in the optical fiber disposing portion 732A, a cooling structure may be provided, and a surface for reflecting return light in a direction perpendicular to the extending direction of each optical fiber 720 or a surface for shielding light may be provided.

Configuration Example of Output Unit

Next, a configuration example of an output unit that can be used for the laser apparatus according to the seventh and eighth embodiments will be described. FIG. 14 is a schematic configuration diagram of the output unit. The output unit 738 includes an end cap 738a, a glass capillary 738b, a light absorber 738c, a housing 738d, and a plurality of adhesive layers 738e. Hereinafter, a case of using the laser apparatus 700 according to the seventh embodiment will be described.

The end cap 738a is a columnar member made of quartz glass and is fixed to the inner hole at one end of the housing 738d with the adhesive layer 738e. An antireflection film is formed on an end surface 738aa to which the laser beam L76 of the end cap 738a is input. On an end surface of the end cap 738a opposite to the end surface 738aa, one end on a side where the coating of the output optical fiber 740 is removed and a glass portion 740a is exposed is fusion spliced.

The glass capillary 738b is a cylindrical member made of quartz glass and is fixed to the inner hole of the cylindrical light absorber 738c at the other end of the housing 738d with the adhesive layer 738e. The glass portion 740a of the output optical fiber 740 is fixed to the inner hole of the glass capillary 738b with the adhesive layer 738e. The light absorber 738c is made of metal, for example, and is fixed to the inner hole of the housing 738d with the adhesive layer 738e.

The laser beam L76 condensed by the condensing lens 737 is coupled to the output optical fiber 740 via the end cap 738a. Here, the diameter of the end cap 738a is larger than the core diameter of the output optical fiber 740. As a result, when the laser beam L76 is input to the end cap 738a, the power density of the light at the end surface 738aa is reduced and excessive temperature rise of the antireflection film and damage due to heat are prevented.

Most of the laser beam L76 coupled to the output optical fiber 740 propagates through the core portion, but a part of the laser beam L76 propagates through the cladding portion in a cladding mode. When the light in the cladding mode reaches the adhesive layer 738e having a refractive index higher than air between the glass portion 740a and the glass capillary 738b, the light leaks to the outside of the cladding portion and becomes leak light. The leak light passes through the glass capillary 738b and reaches the light absorber 738c where the leak light is converted to heat. This prevents the leak light from reaching the coating of the output optical fiber 740 and burning the coating. A structure that uses such light in the cladding mode as leak light is also called a cladding mode stripper structure.

In addition, the housing 738d has a cooling structure such as air cooling or water cooling, and an excessive temperature rise of the light absorber 738c is prevented.

### Ninth Embodiment

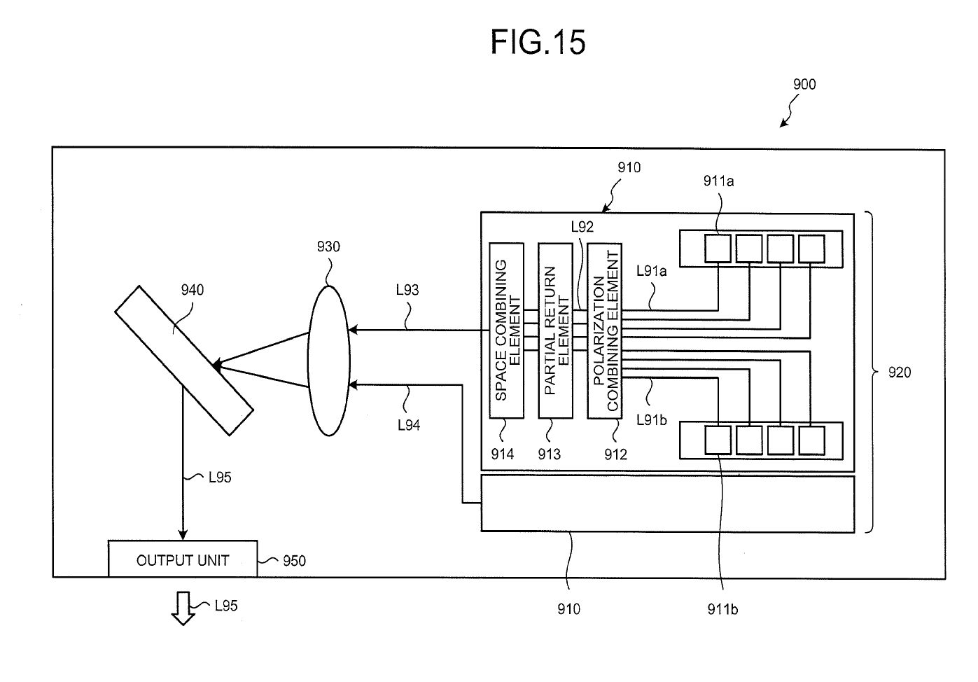

FIG. 15 is a schematic configuration diagram of a laser apparatus according to a ninth embodiment. A laser apparatus 900 according to the ninth embodiment includes a laser module group 920 including a plurality of (two in this embodiment) laser modules 910, a condensing lens 930, a transmission type diffraction grating 940 which is a chromatic dispersion element functioning as a wavelength multiplexing component, and an output unit 950.

Each of the laser modules 910 includes a plurality of (four in the present embodiment) semiconductor laser elements 911a and 911b, a polarization combining element 912, a partial return element 913, and a space combining element 914.

The semiconductor laser elements 911a and 911b output laser beams L91a and L91b each having the same wavelength. The polarization combining element 912 polarization-combines the laser beams of the four linearly polarized waves output from the respective semiconductor laser elements 911a and the laser beams of the four linearly polarized waves output from the respective semiconductor laser elements 911b, and outputs a polarization-combined laser beam L92 to the partial return element 913. For example, the polarization combining element 912 can perform polarization combining by passing the laser beam L91b output from each semiconductor laser element 911b through a wave plate so as to make the polarization orthogonal to the laser beam L91a.

The partial return element 913 is constituted by a partial mirror, returns a part of the input laser beams L92a and L92b to the output semiconductor laser elements 911a and 911b, and outputs the remaining part to the space combining element 914. As a result, the wavelengths of the laser beams L91a and L91b are locked and the wavelength is stabilized. The space combining element 914 spatially combines the input laser beams L92a and L92b and outputs the input laser beams L92a and L92b as a space combined laser beam L93.

The spatially combined laser beams L93 and L94 output respectively from the laser modules 910 have different wavelengths. The condensing lens 930 condenses the laser beams L93 and L94 on the diffraction grating 940.

Here, as in the third embodiment, an angle formed by an optical axis of the condensing lens 930 and a normal line to the principal surface of the diffraction grating 940, a pitch of the diffraction grating 940, and a wavelength of each of the laser beams L93 and L94 and a positional relationship of the optical path are adjusted. Diffraction angles of first-order diffracted light beams of the laser beams L93 and L94 coincide with each other. Therefore, the laser beams L93 and L94 are multiplexed by the diffraction grating 940 to become a laser beam L95. The laser beam L95 is output from the laser apparatus 900 via the output unit 950. The output unit 950 is, for example, a multi-mode optical fiber. In order to center the output unit 950 in accordance with the optical path of the laser beam L95, a centering stage may be provided in the output unit 950. Further, since the output unit 950 has a high temperature, a cooling mechanism may be provided.

In the ninth embodiment, the partial return element 913 is placed inside the housing of the laser module 910, but the partial return element 913 may be placed outside the housing. In the ninth embodiment, the partial return element 913 is placed at a subsequent stage of the polarization combining element 912, but may be placed at a preceding stage of the polarization combining element 912.

### Tenth Embodiment

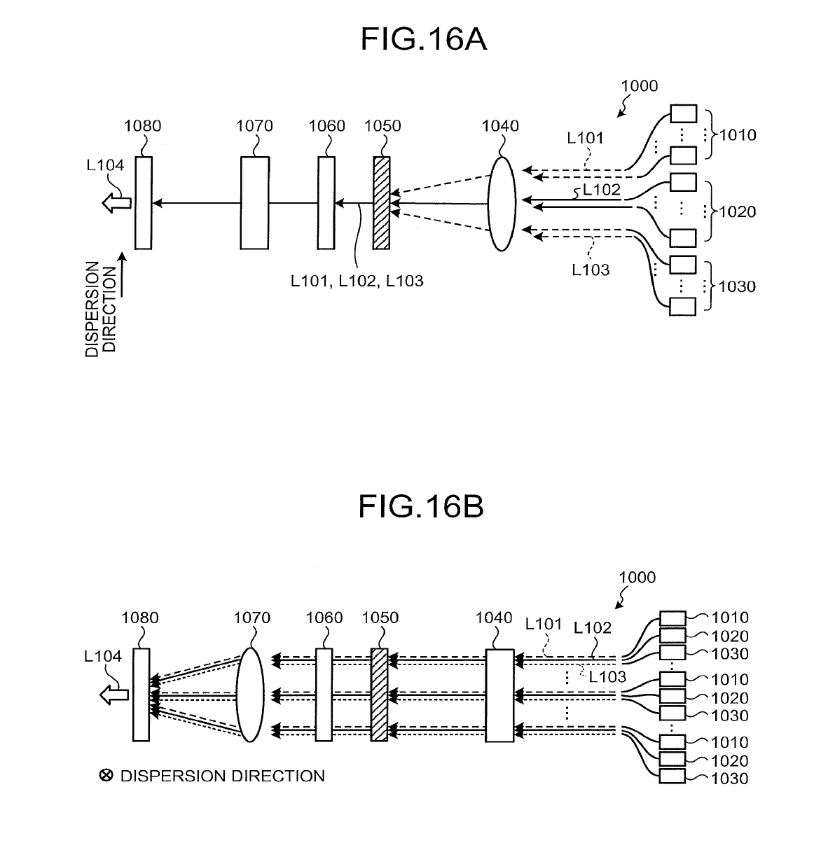

Each of FIGS. 16A and 16B is a schematic configuration diagram of a main part of a laser apparatus according to a tenth embodiment. A laser apparatus 1000 according to the tenth embodiment includes a plurality of laser modules 1010, 1020, and 1030, a first cylindrical lens 1040, a diffraction grating 1050 which is a chromatic dispersion element functioning as a wavelength multiplexing component, a partial return element 1060, a second cylindrical lens 1070, and an output unit 1080. Note that FIG. 16A is a view of the laser apparatus 1000 as viewed from a direction perpendicular to a light dispersion direction by the diffraction grating 1050, and FIG. 16B is a view as seen from a direction parallel to the dispersion direction. In practice, the optical path is bent in the diffraction grating 1050. Therefore, when viewed from the direction perpendicular to the dispersion direction, the respective elements from the first cylindrical lens 1040 to the second cylindrical lens 1070 are disposed with an angle before and after the diffraction grating 1050. However, in FIG. 16A, For simplicity of explanation, each element is illustrated while being arranged in series.

In the tenth embodiment, each laser module 1010 is located at substantially the same position in the dispersion direction and is arranged in a depth direction of a paper sheet of FIG. 16A. However, for illustrative purposes, the laser modules 1010 are illustrated while being arranged in a direction parallel to the paper sheet. Likewise, the laser modules 1020 and 1030 are also located at substantially the same position in the dispersion direction, but the laser modules 1020 and 1030 are illustrated while being arranged in a direction parallel to the paper sheet for explanation. However, the laser modules 1010, 1020, and 1030 are at different positions in the dispersion direction.

Each laser module 1010 has the same configuration as the laser module 910 of the laser apparatus 900 according to the ninth embodiment, for example, and outputs a laser beam L101 having substantially the same wavelength. Each laser module 1020 also has the same configuration as the laser module 910 of the laser apparatus 900 according to the ninth embodiment, for example, and outputs a laser beam L102 having substantially the same wavelength. Each laser module 1030 also has the same configuration as the laser module 910 of the laser apparatus 900 according to the ninth embodiment, for example, and outputs a laser beam L103 having substantially the same wavelength. However, the wavelengths of the laser beams L101, L102, and L103 are different from each other. For example, the laser beam L101 has the shortest wavelength and the laser beam L103 has the longest wavelength.

The laser beams L101, L102, and L103 are transmitted through an optical fiber and input to the first cylindrical lens 1040. At this time, the optical paths of the laser beams L101, L102, and L103 are parallel to each other and are parallel to the optical axis of the first cylindrical lens 1040.

The first cylindrical lens 1040 condenses the laser beams L101, L102, and L103 in the dispersion direction and inputs the laser beams L101, L102, and L103 to the diffraction grating 1050.

Here, as in the third embodiment, an angle formed by an optical axis of the first cylindrical lens 1040 and a normal line to the principal surface of the diffraction grating 1050, a pitch of the diffraction grating 1050, and a wavelength of each of the laser beams L101, L102, and L103 and a positional relationship of the optical path are adjusted. Diffraction angles of first-order diffracted light beams of the laser beams L101, L102, and L103 coincide with each other. Therefore, the laser beams L101, L102, and L103 are diffracted by the diffraction grating 1050 so that the optical paths are coincident in the dispersion direction.

The partial return element 1060 is constituted by a partial mirror, returns a part of the input laser beams L101 and L102, and L103 to the output semiconductor laser elements in each of the laser modules 1010, 1020, and 1030, and outputs the remaining part to the second cylindrical lens 1070. As a result, the wavelengths of the laser beams L101, L102, and L103 are locked, and the wavelength is stabilized.

The second cylindrical lens 1070 condenses the laser beams L101, L102, and L103 in a direction perpendicular to the dispersion direction. As a result, the respective laser beams L101, L102, and L103 are multiplexed and become a laser beam L104. The laser beam L104 is output from the laser apparatus 1000 via the output unit 1080.

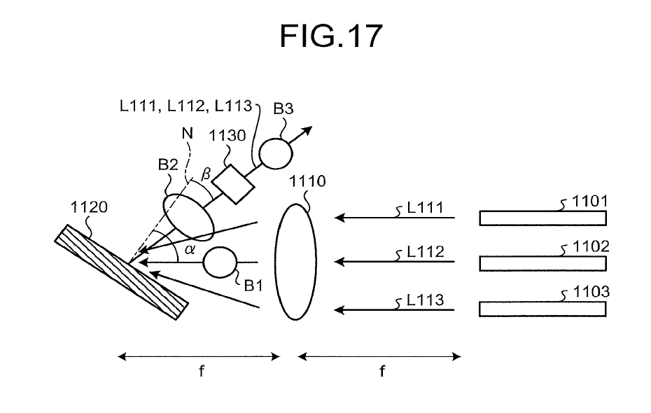

Incidentally, in the case of the configuration including the diffraction grating as in the third, seventh, eighth, ninth, and tenth embodiments, when an incident angle and diffraction angle of light on the diffraction grating are different, the ellipticity of the beam of light after diffraction deviates from 1. In a case where the diffraction grating is a reflective type, there is a problem because an incident angle and diffraction angle are different. Therefore, by using an anamorphic optical system including an anamorphic prism or a cylindrical lens, the ellipticity can be set to 1. FIG. 17 is a schematic diagram of a configuration in which the anamorphic optical system is provided. Optical fibers 1101, 1102, and 1103 output, to a condensing lens 1110, laser beams L111, L112, and L113 having different wavelengths output from the laser module. The condensing lens 1110 condenses the laser beams L111, L112, and L113 on a diffraction grating 1120. The diffraction grating 1120 outputs the laser beams L111, L112, and L113 at the same diffraction angle, and combines the laser beams L111, L112, and L113. Incidentally, a distance between the condensing lens 1110 and front ends of the optical fibers 1101, 1102, 1103, and a distance between the condensing lens 1110 and an incident point on a diffraction surface of the optical fibers 1101, 1102, and 1103 of the diffraction grating 1120 are all set to a focal length f of the condensing lens 1110.

Here, in the dispersion direction of light by the diffraction grating 1120, a beam radius of a beam B1 of the laser beam L112 just before diffraction by the diffraction grating 1120 is ω₁. Further, a beam radius of a beam B2 of the laser beam L112 immediately after diffraction is ω2. Furthermore, a normal line to a diffraction surface of the diffraction grating 1120 is N. Further, an incident angle of the laser beam L112 on the diffraction grating 1120 is α, and a diffraction angle is β. Then, a conversion rate m of the beam of the laser beam L112 by the diffraction grating 1050 is expressed by the following equation.

m=ω₂/ω₁=cos β/cos α

However, as illustrated in FIG. 17, by providing an anamorphic optical system 1130 in the optical path of the laser beam L112, a beam diameter in a dispersion direction of a beam B3 output from an anamorphic optical system 1130 can be converted to ω₁; therefore, the ellipticity can be returned to 1.

In the above embodiment, the wavelength selecting component is a band-pass filter, but a configuration obtained by combining a long wavelength pass filter and a short wavelength pass filter may be used as a wavelength selecting component.

In the above embodiment, transmission type or reflection type is used as the diffraction grating, but it is not limited to either.

Further, the present disclosure is not limited by the above embodiment. The present disclosure encompasses those constituted by appropriately combining the above-described respective constituent elements. Further effects and modifications can be easily derived by those skilled in the art. Therefore, the broader aspects of the present disclosure are not limited to the above embodiments, and various modifications are possible.

According to the present disclosure, effect that can provide a laser apparatus capable of suitably controlling the laser emission wavelength of the light source element to a desired wavelength can be obtained.

What is claimed is:

1. A laser apparatus comprising:
a plurality of light source elements, each of which outputs a laser beam;
a wavelength selecting element disposed in an optical path of each of the laser beams and configured to cause light in a predetermined wavelength band to selectively transmit therethrough; and
a partially transmissive reflector disposed so as to receive the light transmitted through the wavelength selecting element and configured to reflect a part of the input light toward the wavelength selecting element and cause a remaining part to transmit therethrough, wherein
the wavelength selecting element causes a part of each of the laser beams output from each of the light source elements to selectively transmit therethrough, the partially transmissive reflector reflects a part of each of the transmitted laser beams, and the wavelength selecting element causes a part of each of the reflected laser beams to transmit therethrough to return to the light source elements that have output the laser beams, and each of the light source elements preferentially oscillates at a wavelength within a wavelength bandwidth in which each of the laser beams transmits through the wavelength selecting element.

2. The laser apparatus according to claim 1, further comprising a rotation mechanism that rotates the wavelength selecting element so that each of the light source elements preferentially oscillates at a desired wavelength.

3. The laser apparatus according to claim 1, wherein each of the light source elements is a multi-mode laser.

4. The laser apparatus according to claim 1, wherein each of the light source elements is a semiconductor laser element.

5. The laser apparatus according to claim 1, wherein the wavelength selecting element is configured by a band pass filter.

6. The laser apparatus according to claim 1, wherein the wavelength selecting element is configured by combining a long wavelength pass filter and a short wavelength pass filter.

7. The laser apparatus according to claim 1, further comprising a collimating lens that collimates each of the laser beams.

8. The laser apparatus according to claim 7, further comprising an optical fiber and a condensing lens that optically couples each of the laser beams to the optical fiber.

9. The laser apparatus according to claim 8, wherein the optical fiber is a multi-mode fiber.

10. A laser apparatus comprising:
a plurality of light source elements, each of which outputs a laser beam;
a partially branching element disposed so as to receive each laser beam and configured to reflect and branch a part of the input light in a direction forming an angle with respect to a traveling direction of each laser beam and cause a remaining part to transmit therethrough;
a wavelength selecting element disposed in a remaining optical path of each of the reflected and branched laser beams and configured to cause light in a predetermined wavelength bandwidth to transmit therethrough; and
a reflector disposed so as to receive the light transmitted through the wavelength selection element and configured to reflect the input light toward the wavelength selecting element, wherein
the partially branching element selectively branches a part of each of the laser beams output from each of the light source elements, the wavelength selecting element causes a part of each of the branched laser beams to selectively transmit therethrough, the reflector reflects a part of each of the transmitted laser beams toward the wavelength selecting element, the wavelength selecting element causes a part of each of the reflected laser beams to selectively transmit therethrough, the partially branching element reflects a part of each of the transmitted laser beams to return to the light source elements that have output the laser beams, and each of the light source elements preferentially oscillates at a wavelength within a wavelength bandwidth in which each of the laser beams transmits through the wavelength selecting element.

11. The laser apparatus according to claim 10, further comprising a rotation mechanism that rotates the wavelength selecting element so that each of the light source elements preferentially oscillates at a desired wavelength.

12. The laser apparatus according to claim 10, wherein each of the light source elements is a multi-mode laser.

13. The laser apparatus according to claim 10, wherein each of the light source elements is a semiconductor laser element.

14. The laser apparatus according to claim 10, wherein the wavelength selecting element is configured by a band pass filter.

15. The laser apparatus according to claim 10, wherein the wavelength selecting element is configured by combining a long wavelength pass filter and a short wavelength pass filter.

16. The laser apparatus according to claim 10, further comprising a collimating lens that collimates each of the laser beams.

17. The laser apparatus according to claim 16, further comprising an optical fiber and a condensing lens that optically couples each of the laser beams to the optical fiber.

18. The laser apparatus according to claim 17, wherein the optical fiber is a multi-mode fiber.

19. A laser apparatus comprising:
a plurality of light source elements, each of which outputs a laser beam having a different wavelength;
a plurality of wavelength selecting elements each disposed in an optical path of each of the laser beams and each configured to cause light in a predetermined wavelength band to selectively transmit therethrough;
a plurality of partially transmissive reflectors each disposed so as to receive the light transmitted through the wavelength selecting elements, each configured to reflect a part of the input light toward the wavelength selecting elements and each configured to cause a remaining part to transmit therethrough; and
a wavelength multiplexing element disposed at a subsequent stage of each of the partially transmissive reflectors to multiplex each of the laser beams, wherein
each of the wavelength selecting elements causes a part of each of the laser beams output from each of the light source elements to selectively transmit therethrough, each of the partially transmissive reflectors reflects a part of each of the transmitted laser beams, each of the wavelength selecting elements causes a part of each of the reflected laser beams to transmit therethrough to return to the light source elements that have output the laser beams, and each of the light source elements preferentially oscillates at a wavelength within a wavelength bandwidth in which each of the laser beams transmits through each of the wavelength selecting elements.

20. The laser apparatus according to claim 19, further comprising a plurality of rotation mechanisms that each rotate each of the wavelength selecting elements so that a laser of each of the light source elements preferentially oscillates at a desired wavelength.

21. The laser apparatus according to claim 19, wherein each of the light source elements is a multi-mode laser.

22. The laser apparatus according to claim 19, further comprising an optical fiber and a lens that optically couples, to the optical fiber, each of the laser beams multiplexed by the wavelength multiplexing elements.

23. The laser apparatus according to claim 22, wherein the optical fiber is a multi-mode fiber.

24. The laser apparatus according to claim 19, wherein the wavelength multiplexing element includes a diffraction grating.

25. The laser apparatus according to claim 19, wherein the wavelength multiplexing element includes at least one wavelength multiplexing filter.

26. A laser apparatus comprising:
a plurality of light source elements, each of which outputs a laser beam having a different wavelength;
a plurality of partially branching elements each disposed so as to receive each laser beam, each configured to reflect and branch a part of each of the input light in a direction forming an angle with respect to a traveling direction of each laser beam and cause a remaining part to transmit therethrough;
a plurality of wavelength selecting elements each disposed in a remaining optical path of each of the reflected and branched laser beams and each configured to cause light in a predetermined wavelength bandwidth to transmit therethrough;
a plurality of reflectors each disposed so as to receive the light transmitted through the wavelength selection elements and each configured to reflect the input light toward the wavelength selecting elements; and
wavelength multiplexing elements disposed at a subsequent stage of each of the partially branching elements and configured to multiplex each of the laser beams, wherein
each of the partially branching elements selectively branches a part of each of the laser beams output from each of the light source elements, each of the wavelength selecting elements selectively transmits a part of each of the branched laser beams, the reflector reflects a part of each of the transmitted laser beams toward the wavelength selecting elements, each of the wavelength selecting elements causes a part of each of the reflected laser beams to selectively transmit therethrough, each of the partially branching element reflects a part of each of the transmitted laser beams to return to the light source elements that have output the laser beams, and each of the light source elements preferentially oscillates at a wavelength within a wavelength bandwidth in which each of the laser beams transmits through the wavelength selecting elements.

27. The laser apparatus according to claim 26, further comprising a plurality of rotation mechanisms that each rotate each of the wavelength selecting elements so that a laser of each of the light source elements preferentially oscillates at a desired wavelength.

28. The laser apparatus according to claim 26, wherein each of the light source elements is a multi-mode laser.

29. The laser apparatus according to claim 26, further comprising an optical fiber and a lens that optically couples, to the optical fiber, each of the laser beams multiplexed by the wavelength multiplexing elements.

30. The laser apparatus according to claim 29, wherein the optical fiber is a multi-mode fiber.

31. The laser apparatus according to claim 26, wherein the wavelength multiplexing element includes a diffraction grating.

32. The laser apparatus according to claim 26, wherein the wavelength multiplexing element includes at least one wavelength multiplexing filter.

33. A laser apparatus comprising:
a plurality of light source modules each outputting a laser beam having a different wavelength;
wavelength multiplexing elements configured to multiplex each of the laser beams;
a lens disposed between the plurality of light source modules and the wavelength multiplexing elements and configured to condense each of the laser beams to the wavelength multiplexing elements;
a first reflector disposed at a subsequent stage of the wavelength multiplexing elements;
a second reflector disposed at a subsequent stage of the first reflector; and
a gain medium disposed between the first reflector and the second reflector, wherein
the gain medium is optically excited by each of the laser beams to emit light,
the first reflector causes each of the laser beams to transmit thererthrough, and
the first reflector and the second reflector reflect light emitted by the gain medium and constitute an optical resonator for light emitted by the gain medium.
